(19) United States
(12) Patent Application Publication
(10) Pub. No.: US 2025/0116732 A1
(43) Pub. Date: Apr. 10, 2025

(54) CALIBRATION QUALITY CONTROL USING MULTIPLE MAGNETOMETERS

(71) Applicant: Google LLC, Mountain View, CA (US)

(72) Inventors: Shandor Glenn Dektor, Sunnyvale, CA (US); Martin Johannes Kraemer, Mountain View, CA (US); Mark Fralick, San Diego, CA (US); Chuck Tally, Carlsbad, CA (US)

(21) Appl. No.: 18/565,891

(22) PCT Filed: Sep. 22, 2022
(86) PCT No.: PCT/US2022/044349

§ 371 Date: Nov. 30, 2023

(51) Int. Cl. G01R 33/00

(52) U.S. Cl. CPC G01R 33/0017; G01R 33/0005

(57) ABSTRACT

Methods, systems, and apparatus, for calibration quality control using multiple magnetometers. One of the methods includes: receiving measurements by two or more magnetic field sensors of a device over a period of time, wherein each measurement measures a magnetic field at each magnetic field sensor, wherein each measurement at each time point over the period of time includes a vector in one or more spatial axes of a three-dimensional space; computing a difference between the measurements over the period of time, wherein the difference at each time point over the period of time is a result of computing a difference based on one or more pairs of the vectors at the time point; determining that the difference does not remain within a predetermined range over the period of time; and in response, classifying calibration quality of the device as unsuitable for computing a heading of the device.

### BACKGROUND

Sensing the Earth's magnetic field is important to estimating a heading on an electronic device, e.g., a personal electronic device such as a smart watch or a mobile phone. The electronic device can include a single magnetometer, such as a magnetometer in a compass, that can sense the Earth's magnetic field and can estimate the heading of the electronic device using the data related to the Earth's magnetic field.

A well-calibrated magnetometer can improve the accuracy of the estimated heading. It is desirable to have a well-calibrated magnetometer that has an error much less than a threshold in each orientation. For example, for heading estimation, it is desirable to have a well-calibrated magnetometer that has an error much less than the magnitude of the horizontal component of the Earth's magnetic field at the magnetometer. The calibration of the magnetometer can include a scale (and/or skew) calibration and a bias calibration. The scale calibration, the skew calibration, or a combination of these, e.g., Soft Iron calibration, is typically modeled as a non-changing parameter and performed only once. The bias calibration, e.g., Hard Iron calibration, is typically modeled as a changing parameter and may need to be periodically estimated for proper performance.

However, it can be challenging to have a well-calibrated magnetometer and thus it can be challenging to achieve good heading estimation. In some cases, a component inside the electronic device may generate stationary or non-stationary magnetic interferences. Stationary magnetic inferences are relatively fixed over time, for example a magnet. Non-stationary magnetic interferences vary over time. For example, a moveable camera magnet or a wire near the magnetometer could generate a non-stationary magnetic interference. These non-stationary interferences cannot be fixed by traditional calibration procedures.

In some cases, a component inside the electronic device can be re-magnetized when the component is located in close proximity to strong magnetic fields, e.g., an external magnetic field such as from a magnet in a headphone. The re-magnetization of the component can result in an offset or a bias that is greater than the magnitude of the Earth's magnetic field. Thus, it is important to identify the component re-magnetization and quickly obtain new calibrations for best performance.

Heading estimation can also be affected by disturbances to the Earth's magnetic field. In some cases, e.g., in an urban environment, the Earth's field can be disturbed by other fields from ferromagnetic materials, e.g., rebar contained in buildings or materials contained in vehicles.

Some techniques seek to obtain one or more disturbance parameters of the magnetic interferences. For example, the system can obtain the electric current in a nearby wire and can model and estimate a magnetic field affected by the electric current at the magnetometer. However, modeling and estimating the disturbance parameters may be challenging or impossible. For example, for some interference currents, the specific current may be unknown.

Some techniques perform an “always on” field monitoring to monitor calibration quality of the magnetometer by detecting component re-magnetization and to trigger new calibrations. These techniques rely on norm or inclination checks along with device motion to look for field disturbances large enough to cause bias shifts. However, these techniques may miss smaller re-magnetization events and may incur high power cost due to the “always-on” nature and frequent recalibration requests.

### SUMMARY

This specification describes technologies for calibration quality control using multiple magnetometers and multi-magnetometer fusion for disturbance rejection. The techniques use multiple magnetometers in the electronic device to determine the calibration quality of one or more of the multiple magnetometers affected by non-homogeneous magnetic fields inside the device or outside the device. Using the measurements of the multiple magnetometers, the techniques can evaluate the calibration quality of the electronic device and use the calibrated measurements to compute a heading of the electronic device. The techniques can estimate and eliminate non-stationary disturbances by fusing the outputs of two or more magnetometers to produce a single estimate.

The subject matter described in this specification can be implemented in particular embodiments so as to realize one or more of the following advantages. Conventionally, a single magnetometer is used to sense the external magnetic field. However, using the single magnetometer, the magnetic field changes can be indistinguishable from time-varying magnetic field disturbances caused by certain device components in an electronic device and may result in a poor heading estimation of the electronic device. The techniques use multiple magnetometers in the electronic device to monitor the calibration quality of the electronic device and to calibrate the magnetometers for more accurate heading estimation. Instead of performing an “always on” field monitoring that has a high power cost, the techniques can measure the difference of the multiple magnetometers at a predetermined interval and use the difference to determine the calibration quality of the device. The techniques can automatically determine to calibrate the magnetometers if the difference is stable but away from zero. Thus, the techniques can lower the power consumption significantly even though multiple magnetometers are running in the device. Instead of searching for strong field disturbances, the techniques can detect small field disturbances by observing the difference of the multiple magnetometers. Instead of running the calibration algorithm for a long period of time to make sure that non-uniform fields would average out, the techniques can run the calibration algorithms for a shorter interval because the input to the calibration algorithms can be validated based on the difference of the multiple magnetometers. Thus, the techniques can provide faster calibration and can save power consumption in the device. Further, these techniques can increase sensitivity to small changes in the magnetometer calibrations, as well as overall increase the fraction of time the device is operating with a “high quality” calibration.

In some implementations, the techniques can estimate and eliminate non-stationary disturbances by fusing the outputs of two or more magnetometers. For example, the techniques can mitigate disturbances from non-stationary fields due to device components. Therefore, the techniques can enable greater flexibility in component placement in a device.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a diagram of an example electronic device using multiple magnetometers.

FIG. 2 is a diagram of an example system for calibration quality control using multiple magnetometers.

FIG. 3 is a flowchart of an example for calibration quality control using multiple magnetometers.

FIG. 4 is a diagram of an example system for magnetometer fusion.

Like reference numbers and designations in the various drawings indicate like components.

### DETAILED DESCRIPTION

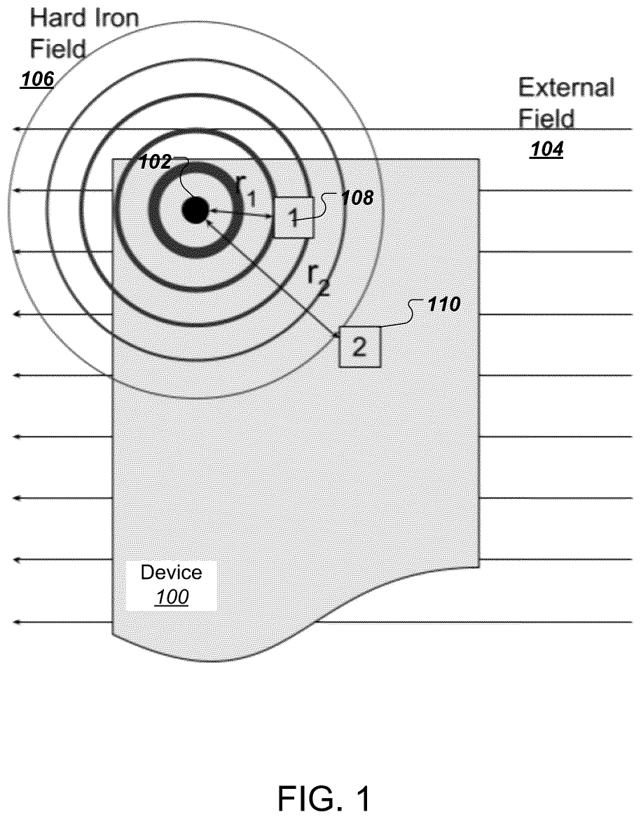

FIG. 1 is a diagram of an example electronic device 100 using multiple magnetic field sensors, e.g., magnetometers. Although FIG. 1 is illustrated for a device having two magnetic field sensors, similar techniques can be applied to a device having more than two magnetic field sensors.

The electronic device 100 can be a personal electronic device, a portable electronic device, or any other kinds of electronic device. For example, the electronic device 100 can be a smart watch, a tablet, a mobile phone, etc.

The electronic device 100 can include multiple magnetic field sensors, e.g., a first magnetometer 108 and a second magnetometer 110. The device can use a magnetometer, e.g., the first magnetometer 108, the second magnetometer 110, or both, to measure a magnetic field or a combination of multiple magnetic fields near the magnetometer. In some implementations, the measurement of a magnetometer can be a three-dimensional (3D) vector, e.g., in x, y, and z directions. In some implementations, the magnetometers 108 and 110 can include a single-axis magnetometer that can sense the magnetic field in a particular direction. For example, a single-axis magnetometer can measure the magnetic field in any one of the x, y, and z directions, or a linear combination thereof, and can generate a single output. In some implementations, the magnetometer can measure a magnetic field over a period of time.

The device 100 is in an external field 104 that is outside the device 100. The external field 104 can be a homogeneous magnetic field. A measurement of the external field 104 can be a constant value across different locations in the device 100. For example, the external field 104 can be the Earth's magnetic field that is homogeneous across time and across locations within a local region of an external space. The device can use sensor data from the one or more of the magnetometers to determine a heading of the device 100 in the horizontal plane. In some implementations, the device can use one or more accelerometers to determine the orientation of the device 100 in the downward or upward direction that is perpendicular to the horizontal plane. The heading of the device 100 can be a three-dimensional (3D) vector indicating a direction in the 3D space determined using one or more magnetometers, one or more accelerometers, or both.

For example, the first magnetometer 108 can measure the direction of the horizontal component of the Earth's magnetic field. The device 100 can determine the direction of the device 100 relative to the direction of the horizontal component of the Earth's magnetic field. Based on comparing the direction of the field measured by the device 100 and the direction of the horizontal component of the Earth's magnetic field, the device 100 can determine the heading of the device 100. In some implementations, the device 100 can determine the heading of the device using measurements from a magnetometer and an accelerometer e.g., through the Triad method (e.g., https://en.wikipedia.org/wiki/Triad_method), or other approaches to heading estimation and/or initialization.

A hard iron field 106 is shown in FIG. 1. The hard iron field 106 is attached to the rigid body of the electronic device 100. That is, the hard iron field 106 moves with the electronic device 100. The hard iron field 106 can be caused by re-magnetization events in which the temporary presence of large magnetic fields induce changes in the magnetization of hardware components in the device, e.g., screws in the device. In some implementations, the hard iron field 106 can vary with the changes in temperature. The hard iron field 106 can be a non-homogeneous field inside the device 100. The hard iron field 106 can be stronger closer to its center 102 and can be weaker away from its center 102. For example, a magnitude of a measurement of the hard iron field 106 from the first magnetometer 108 can be larger than a magnitude of a measurement of the hard iron field 106 from the second magnetometer 110 because the first magnetometer 108 is closer to the center 102 of the hard iron field 106 than the second magnetometer 110.

In some implementations, the hard iron field 106 can be a static field that is unchanged over a period of time. For example, a measurement of the hard iron field 106 from the first magnetometer 108 can be a first constant over a period of time. A measurement of the hard iron field 106 from the second magnetometer 110 can be a second constant over a period of time. In some implementations, the hard iron field 106 can be a non-static field that changes over a period of time.

In some implementations, the hard iron field 106 can be from magnetization of a hardware component that has a fixed location in the device 100, and thus the relative locations between the hard iron field 106 and the two magnetometers 108 and 110 can be fixed. In some implementations, the hard iron field 106 can be from magnetization of a hardware component that can move in the device 100, and thus the relative locations between the hard iron field 106 and the two magnetometers 108 and 110 may not be fixed.

In general, taking the difference of two or more synchronized magnetometers at different locations on the device 100 can be a measurement of a spatial derivative. The measurement of the spatial derivative over time can be used to determine properties of the magnetic field near the two or more synchronized magnetometers.

In some cases, the difference of two or more synchronized magnetometers can be used to determine a homogeneous external field, e.g., an Earth field or the external field 104, at the device 100. The homogeneous external field is independent of the location and the orientation of the device 100. When the device 100 determines that the difference of the two or more synchronized magnetometers does not change over time, e.g., a zero derivative of the difference, the device 100 can determine that the magnetic field at the device 100 is a homogeneous magnetic field.

In some cases, a magnetized component on the device 100 can cause a non-homogeneous but static field, e.g., a hard iron field 106. The difference of the two or more synchronized magnetometers can be a non-zero value that is constant over time and the difference can be independent of the motion of the device 100. For example, the difference of the two or more synchronized magnetometers can be the same constant value when the device 100 is rotating or static. When the device 100 determines that the difference of the two or more synchronized magnetometers can be the same non-zero constant value over time and can be independent of the motion of the device 100, the device 100 can determine that the magnetic field at the device 100 includes a non-homogeneous static field inside the device, e.g., caused by magnetization of a component inside the device 100, and that the external field is homogeneous.

In some cases, a component outside the device 100 can cause a non-homogeneous field, e.g., a non-homogeneous external field. The difference of the two or more synchronized magnetometers can be a non-zero value that may not be constant when the device 100 is moving. When the device 100 determines that the difference of the two or more synchronized magnetometers is a non-zero value that is not constant when the device 100 is moving, the device 100 can determine that the magnetic field at the device 100 includes a non-homogeneous external field. In some implementations, the device 100 can measure the non-homogeneous external field while moving.

For example, each of the magnetometers 108 and 110 can generate a measurement that measures a magnetic field that includes the external field 104 and the hard iron field 106 at the respective location of the magnetometer. For example, the magnetic measurement of the first magnetometer 108 at time t₁ and the magnetic measurement of the second magnetometer 110 at time t₁ can be formulated as the following:

$${X}_{1} ( t ) = R ( t ) {H}_{EF} ( t , {r}_{1} ) + {H}_{HI} ( t , {r}_{1} ) \qquad ( 1 )$$

$${X}_{2} ( t ) = R ( t ) {H}_{EF} ( t , {r}_{2} ) + {H}_{HI} ( t , {r}_{2} ) \qquad ( 2 )$$

Here, Xᵢ(t)=[xᵢ(t), yᵢ(t), zᵢ(t)]^{T} are the body-frame magnetic fields at the sensor i at time t, H_{EF}(t, r₁) and H_{EF}(t, r₂) are the vectors of the external field 104 at time t and locations r₁ and r₂, respectively. R(t) is a rotation matrix at time t that can be applied to the external field 104. R(t) is the same for both magnetometers 108 and 110 because the device 100 has a rigid body. H_{HI} is the vector of the hard iron field 106 and can change over time and depends on the sensor location on the device. For example, H_{HI}(t,r₁) is the field strength of the hard iron field at time t and at the first magnetometer that has a distance r₁ from the center 102 of the hard iron field. H_{HI}(t,r₂) is the field strength of the hard iron field at time t and at the second magnetometer that has a distance r₂ from the center 102 of the hard iron field 106.

In general, the hard-iron field on a device is highly inhomogeneous and is due to the presence of one or more magnetic elements on the device. FIG. 1 shows an example where H_{HI} can be dependent on the distance r from the magnetometer to the center 102 of the hard iron field 106. In this case, the field strength of the hard iron field 106 can be inversely proportional to the distance r from the magnetometer to the center 102 of the hard iron field 106, as the following:

$${H}_{HI} ( t , r ) = \frac{{H}_{HI} ( t )}{r} . \qquad ( 3 )$$

In some implementations, the device 100 can monitor the calibration quality of the magnetometers 108 and 110 by determining the magnetic disturbances caused by the hard iron field 106. In some implementations, the device 100 can determine the hard iron field component in the magnetic measurement and can perform calibration of the magnetometer, e.g., removing the hard iron field component from the magnetic measurement. The calibrated output at time t>t₁ can be formulated as the following:

$${X}_{1 , cal} ( t ) = {X}_{1} ( t ) - {H}_{HI , est} ( {t}_{1} , {r}_{1} ) \qquad ( 4 )$$

$${X}_{2 , cal} ( t ) = {X}_{2} ( t ) - {H}_{HI , est} ( {t}_{1} , {r}_{2} ) \qquad ( 5 )$$

Here, X_{1,cal}(t) is the calibrated measurement of the first magnetometer 108 at time t, X_{2,cal}(t) is the calibrated measurement of the second magnetometer 110 at time t, and H_{HI,est}(t₁,r₁) and H_{HI,est}(t₁,r₂) and are the calibration estimates obtained at time t₁ and locations r₁ and r₂, respectively. The difference of the calibrated measurements of the two magnetometers 108 and 110 can be formulated as the following, where the differences due to local field variation and calibration error are separated out.

$$\begin{matrix}Δ ( t ) = {X}_{1 , cal} ( t ) - {X}_{2 , cal} ( t ) \\ = ( {X}_{1} ( t ) - {H}_{HI , est} ( {t}_{1} , {r}_{1} ) ) - ( {X}_{2} ( t ) - {H}_{HI , est} ( {t}_{1} , {r}_{2} ) ) \\ = ( R ( t ) {H}_{EF} ( t , {r}_{1} ) + {H}_{HI} ( t , {r}_{1} ) - {H}_{HI , est} ( {t}_{1} , {r}_{1} ) ) - \\ ( R ( t ) {H}_{EF} ( t , {r}_{2} ) + {H}_{HI} ( t , {r}_{2} ) - {H}_{HI , est} ( {t}_{1} , {r}_{2} ) ) \\ = {\underbrace{( R ( t ) ( {H}_{EF} ( t , {r}_{1} ) - {H}_{EF} ( t , {r}_{2} ) ) )}}_{local field variation} + {\underbrace{( {H}_{HI} ( t , {r}_{1} ) - {H}_{HI , est} ( {t}_{1} , {r}_{1} ) )}}_{cal 1 error} - \\ {\underbrace{( {H}_{HI} ( t , {r}_{2} ) - {H}_{HI , est} ( {t}_{1} , {r}_{2} ) )}}_{cal 2 error}\end{matrix}$$

When both magnetometers 108 and 110 are well calibrated, e.g. the hard-iron field hasn't changed (H_{HI,est}(t₁,r₁)=H_{HI}(t, r₁) and H_{HI,est}(t₁, r₂)=H_{HI}(t, r₂)), and in a homogenous external field (H_{EF}(t, r₁)=H_{EF}(t, r₂)), then difference of the calibrated measurements of the two magnetometers 108 and 110 is zero:

$${Δ}_{homogenous field , well calibrated} ( t ) = {X}_{1 , cal} ( t ) - {X}_{2 , cal} ( t ) = 0 \qquad ( 6 )$$

In some implementations, the hard iron field 106 can change over a time, e.g., due to a re-magnetization event. For example, at a time t₂ that is a period of time after the time t₁, the hard iron field 106 can be different. However, the calibration is still using the hard iron field measured at the time t₁. The device 100 can compute the difference of the calibrated measurements of the two magnetometers 108 and 110, as the following:

$$\begin{matrix}Δ ( {t}_{2} ) = {X}_{1 , cal} ( {t}_{2} ) - {X}_{2 , cal} ( {t}_{2} ) \\ = ( {X}_{1} ( {t}_{2} ) - {H}_{HI , est} ( {t}_{1} , {r}_{1} ) ) - ( {X}_{2} ( {t}_{2} ) - {H}_{HI , est} ( {t}_{1} , {r}_{2} ) ) \\ = {\underbrace{( R ( {t}_{1} ) ( {H}_{EF} ( {t}_{2} , {r}_{1} ) - {H}_{EF} ( {t}_{2} , {r}_{2} ) ) )}}_{local field variation} + \\ {\underbrace{( {H}_{HI} ( {t}_{2} , {r}_{1} ) - {H}_{III , est} ( {t}_{1} , {r}_{1} ) )}}_{cal 1 error} - {\underbrace{( {H}_{HI} ( {t}_{2} , {r}_{2} ) - {H}_{HI , est} ( {t}_{1} , {r}_{2} ) )}}_{cal 2 error}\end{matrix} \qquad ( 7 )$$

For consistent external fields, the external field component H_{EF} from the two measurements cancel. Applying equation (3) from our example system, the difference of the measurements of the two magnetometers 108 and 110 can be the following:

$$\begin{matrix}Δ ( {t}_{2} ) = ( {H}_{HI} ( {t}_{2} , {r}_{1} ) - {H}_{HI , est} ( {t}_{1} , {r}_{1} ) ) - ( {H}_{HI} ( {t}_{2} , {r}_{2} ) - {H}_{HI , est} ( {t}_{1} , {r}_{2} ) ) \\ = ( {H}_{HI} ( {t}_{2} ) - {H}_{HI} ( {t}_{1} ) ) ( \frac{1}{{r}_{1}} - \frac{1}{{r}_{2}} ) \\ = Δ {H}_{HI} ( \frac{1}{{r}_{1}} - \frac{1}{{r}_{2}} )\end{matrix} \qquad ( 8 )$$

Because the positions of the two magnetometers relative to the hard iron field are fixed, e.g., the

$$( \frac{1}{{r}_{1}} - \frac{1}{{r}_{2}} )$$

is a constant value, the difference of the measurements of the two magnetometers 108 and 110 can measure the change of the hard iron field 106. The change of the hard iron field is the hard iron change ΔH_{HI}. In some implementations, the hard iron change of the hard iron field 106 can be slow, e.g., can be a constant term over a period of time. For example, the hard iron change can be a constant after the end of a re-magnetization event. The device can measure the hard iron change using equation (8) with known positions of the multiple magnetometers. In some implementations, the hard iron change of the hard iron field 106 can be a rapid change over time. Correspondingly, the difference of the measurements of the two magnetometers 108 and 110 can show a rapid change, e.g., a field anomaly can be detected.

The device 100 can monitor the calibration quality and the quality of the local field, e.g., the hard iron field 106 from a component on the device 100. The device 100 can compute a mean and a standard deviation of the difference of the two or more synchronized measurements from the multiple magnetometers. When the device 100 determines that the mean of the difference of the two or more synchronized magnetometers is zero over time, the device 100 can determine that the magnetometers are well calibrated. When the device 100 determines that a value computed based on the two or more synchronized magnetometers (e.g., the mean of the difference of the two or more synchronized magnetometers, the difference of the means of the two or more synchronized magnetometers, the difference of the mean of the norms of the two or more synchronized magnetometers, or a combination of these) is a non-zero constant over time while the device is moving, the device 100 can determine that the magnetometers needs to be calibrated for a non-homogeneous static field inside the device 100. When the device 100 determines that the mean of the difference of the two or more synchronized magnetometers is a non-zero value that changes over time while the device 100 is moving, the device 100 can determine that the device 100 is in a non-homogeneous external field.

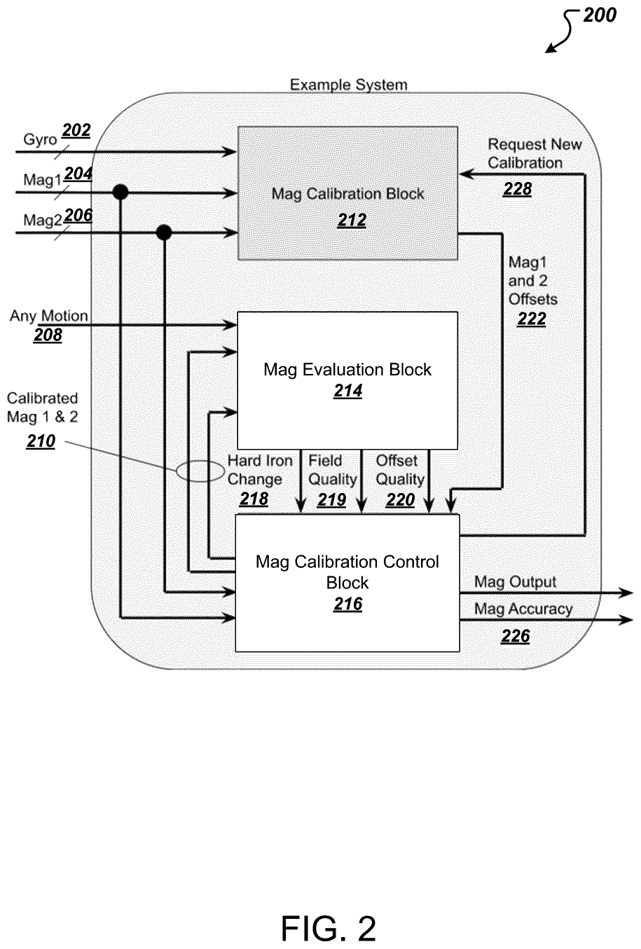

FIG. 2 is a diagram of an example system 200 for calibration quality control using multiple magnetometers. The system 200 can be a part of an electronic device that has multiple magnetic field sensors, e.g., the electronic device 100 of FIG. 1 that has two magnetometers. Although FIG. 2 is illustrated for a system of a device having two magnetic field sensors, similar techniques can be applied to a system of a device having more than two magnetic field sensors.

The system 200 can include a Magnetometer Evaluation block 214. The Magnetometer Evaluation block 214 can evaluate the calibration quality of the magnetometers using measurements of multiple magnetometers, and can communicate to other blocks regarding a hard iron change 218, the field quality 219, the offset quality 220, or a combination of these. In some implementations, the Magnetometer Evaluation block 214 can compute the difference of the measurements of multiple magnetometers and can evaluate the difference via a mean computation, a standard deviation computation, or a combination of both. For example, the block 214 can compute the difference between the first measurement 204 from the first magnetometer and the second measurement 206 from the second magnetometer over a period of time. The block 214 can compute the mean of the difference over the period of time, and can compute the standard deviation of the difference over the period of time. From the mean and standard deviation of the difference, the block 214 can determine whether the hard iron, e.g., magnetic offset, has changed.

For example, the block 214 can detect disturbances caused by a non-homogeneous static field inside the device, e.g., a hard iron field 106. The block 214 can detect a field anomaly, e.g., disturbances caused by a non-homogeneous field outside the device. A field anomaly occurs when there is a non-homogeneous field outside the device that generates disturbances to the magnetic measurements of the multiple magnetometers. The block 214 can send information regarding the detected magnetic field disturbances to the device to prevent the usage of unreliable magnetic measurements, e.g., preventing the device from using the magnetic measurements to compute an inaccurate heading of the device. For example, the system can determine to use gyro integration for a while to prevent a poor external field from affecting the heading estimate.

The block 214 can receive measurements from the multiple magnetometers as input. In some implementations, the multiple magnetometers have been previously calibrated and the block 214 can receive calibrated measurements 210 from the multiple magnetometers as input. For example, the block 214 receives a first calibrated measurement from the first magnetometer and a second calibrated measurement from the second magnetometers. For example, a calibrated measurement can include a scale and/or skew calibration, a bias calibration, or both.

The measurement (or calibrated measurement) can include measurement data over a period of time. The measurement at each time point over the period of time can be a 3D vector in x, y, and z measuring a magnetic field at the corresponding magnetometer in each of the three axes. The block 214 can include a synchronizer that can synchronize over the period of time the measurements obtained from the two magnetometers and can generate synchronized measurements. The block 214 can compute a difference of the synchronized measurements from the two magnetometers. For example, the difference can include a 3D vector in x, y, and z measuring the difference of the measurements in each of the three axes.

The block 214 can determine disturbances based on the difference of the measurements. In some implementations, the block 214 can compute a mean and a standard deviation of the difference of the measurements over the period time. In some implementations, the block 214 can include a low pass filter that can be configured to filter out the high frequency components, e.g., noise, in the difference and can calculate a mean of the filtered difference.

In some implementations, the block 214 can include a logic component that can take as input the mean and standard deviation of the difference of the measurements and can generate, as output, a calibration quality result. In some implementations, the logic component can take a motion signal 208 that indicates whether there is any motion in the device. For example, the motion signal 208 can indicate whether the device was moving when the two magnetometers performed the measurements during the period of time. In some implementations, e.g., in Android devices, the motion signal 208 is called “significant motion” (https://developer.android.com/guide/topics/sensors/sensors_motion #sensors-motion-significant). The motion signal 208 can be high when the device is in motion and can be low when the device is sitting still and not in motion. Using the motion signal 208, the Magnetometer Evaluation block 214 can determine whether a hard iron source is connected to the rigid body of the device or whether the hard iron source is a magnetic field source that is close to the device, such as a laptop speaker or a earbud case.

The block 214 can generate a calibration quality monitoring result that indicates whether a hard iron change 218 has occurred. For example, the calibration quality monitoring result can indicate whether there is a non-homogeneous static field caused by a hard iron field inside the device.

In some implementations, the system can compare the difference of the measurements to a predetermined range close to zero over the period of time. The system can determine that the difference remains inside the predetermined range over the period of time, and in response, the system can determine that the calibration quality of the device is good and the calibration quality of the device is suitable for computing a heading of the device.

In some implementations, the system can compare the difference of the measurements to a non-zero constant over the period of time. The system can determine that the difference stays near the non-zero constant over the period of time, and in response, the system can determine that the calibration quality can be affected by a non-homogeneous static field inside the device.

In some implementations, the system can determine whether the standard deviation of the difference over the period of time is smaller than a threshold and whether the mean is approximately zero. If the system determines that the standard deviation is smaller than the threshold and the mean is approximately zero, the system can determine that the device is well calibrated. If the system determines that the standard deviation is smaller than the threshold and the mean is not approximately zero, the system can determine that a hard iron change has occurred and the device needs to be calibrated.

In some implementations, the block 214, e.g., the logic component of the block 214, can generate a calibration quality monitoring result that indicates the field quality 219, e.g., whether a field anomaly has occurred. In some implementations, the system can compare the standard deviation of the difference of the measurements over the period of time to a threshold. The system can determine that the standard deviation exceeds the threshold over the period of time, and in response, the system can determine that the calibration quality is affected by a non-homogeneous field outside the device, e.g., a field anomaly.

The system 200 can include a Magnetometer Calibration Control block 216. The block 216 can evaluate the calibration quality of measurements from the two magnetometers. The block 214 can send the calibration quality monitoring result, e.g., the hard iron change signal 218, the field quality 219, the offset quality 220, or a combination of these, to the Magnetometer Calibration Control block 216 that controls the magnetic field calibration and the hard iron correction. The Magnetometer Calibration Control block 216 can implement a master control for a magnetic calibration algorithm to be applied to the measurements 204 and 206 of the two magnetometers. In some implementations, the Magnetometer Calibration Control block 216 can correct the measurements 204 and 206 for the hard iron change or offsets.

For example, the Magnetometer Calibration Control block 216 can receive the hard iron change 218, the field quality 219, the offset quality 220, or a combination of these from the block 214. Based on the information from block 214, the Magnetometer Calibration Control block 216 can generate an accuracy score 226 indicating the calibration quality of the first measurement, the second measurement, or both. If the calibration quality is poor, e.g., if the accuracy score 226 is below a threshold, the Magnetometer Calibration Control block 216 can generate a “request new calibration” signal 228 to trigger the calibration of the one or more magnetometers of the device. After the system 200 receives the output signal 228 that triggers the calibration, the system 200, e.g., the Magnetometer Calibration block 212 can perform the calibration of the first magnetometer, the second magnetometer, or both.

In some implementations, the hard iron change signal 218 can include a “Start Calibration” signal indicating whether the device needs to be calibrated or re-calibrated. In some implementations, the block 216 can receive an offset quality signal 220 indicating whether the previously determined offsets 222 for the two magnetometers are accurate. In some implementations, the block 216 can generate a Magnetometer Accuracy 226 signal indicating whether the calibrated measurements 210 for the two magnetometers are accurate.

For example, after detecting a hard iron change 218, the block 216 can send a “Request New Calibration” signal 228 to the Magnetometer Calibration Block 212 to initiate calibration. After detecting a field anomaly indicated in the field quality signal 219, the block 216 can send a notification signal to the Magnetometer Calibration Block 212 to notify of the detected field anomaly and e.g. pause calibration routines. In some examples, after detecting a change in the calibration accuracy, the block 214 can send a signal indicating the change of the accuracy, e.g., the “Offset Quality” signal 220 or the “Field Quality” signal 219, to consumers of the calibrated magnetic field measurement for their usage.

The system 200 can include a Magnetometer Calibration block 212 that can calibrate one or more of the multiple magnetometers. For example, the Magnetometer Calibration block 212 can calibrate both magnetometers at the same time by performing a magnetic gyro calibration. In some implementations, a block 212 can receive as input a gyro measurement 202, a first magnetometer measurement 204 from the first magnetometer over a period of time, and a second magnetometer measurement 206 from the second magnetometer over the period of time. The Magnetometer Calibration block 212 can generate first and second offsets 222 from the inputs, and can use the first offset and the second offset 222 to perform calibration on the magnetometer measurements.

In some implementations, the Magnetometer Calibration block 212 can send the first and second offsets 222 for the two magnetometers to the Magnetometer Calibration Control block 216 in order to test the accuracy of the generated offset. For example, the block 216 can generate calibrated measurements 210 for the input measurements 204 and 206 from the two magnetometers over a period of time using the offsets 222. The block 214 can generate a difference of the calibrated measurements over the period of time, and can determine the magnetometer accuracy 226. For example, if the system determines that the difference of the calibrated measurements remains inside a predetermined range, e.g., close to zero, over the period of time, the system can determine that the offsets 222 are accurate. If the system determines that the difference of the calibrated measurement does not remain inside a predetermined range, e.g., is not close to zero, over the period of time, the system can determine that the offsets 222 are not accurate.

In some implementations, after the calibration of the magnetometers is completed, the Magnetometer Calibration block 212 can send a signal to a sensor correction module (not shown in FIG. 2). The sensor correction module can be configured to generate a calibration accuracy score, and the signal can trigger a change of a calibration accuracy score from low to high, indicating that the magnetometers have been well calibrated.

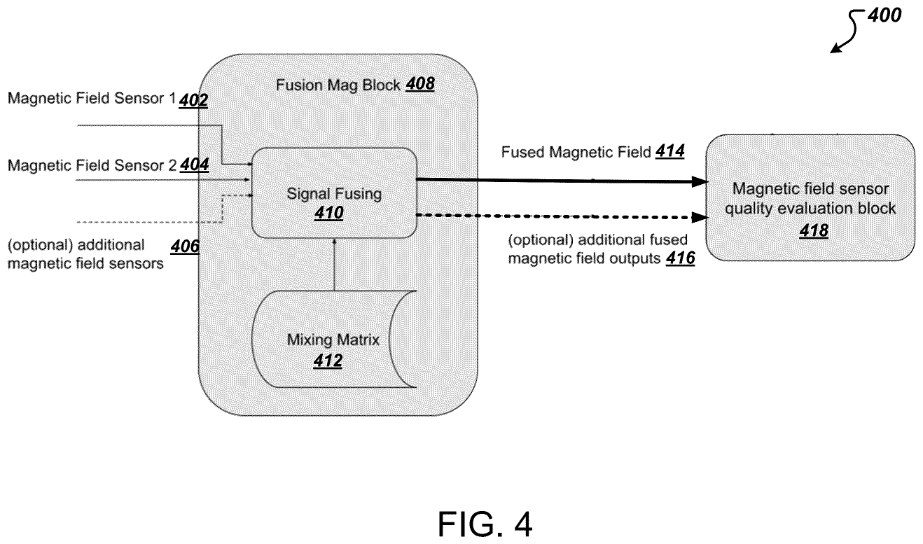

FIG. 4 is a diagram of an example system 400 for magnetometer fusion using multiple magnetometers. The system 400 can be a part of an electronic device that has multiple magnetic field sensors, e.g., the electronic device 100 that has two magnetometers. Although FIG. 4 is illustrated for a system of a device having two magnetic field sensors, similar techniques can be applied to a system of a device having more than two magnetic field sensors.

The system 400 can receive measurements by two or more magnetic field sensors of a device over a period of time. Each measurement can measure a magnetic field at each magnetic field sensor. In some implementations, the two or more magnetic field sensors can include two or more magnetometers.

The system 400 can include a Magnetometer Fusion block 408. The Magnetometer Fusion block 408 can fuse the outputs of the two or more magnetic field sensors, e.g., magnetometers, to produce a fused magnetometer output. For example, the block 408 can receive as input the first measurement 402 of the magnetic field sensor 1 and the second measurement 404 of the magnetic field sensor 2 and can generate a fused magnetic field 414 from the measurements 402 and 404. In some implementations, the block 408 can receive measurements 406 from additional magnetic field sensors, and can generate additional fused magnetic field outputs 416 from the measurements 402, 404, and 406. The fused magnetic field 414 (and 416) can be a combination of the measurements of the two or more magnetic field sensors. By combining the measurements from the two or more magnetic field sensors, the effect of disturbance can be separated from the measurement of the external magnetic field, e.g., the Earth field.

In some implementations, the system can estimate modeling inaccuracies at the two or more magnetic field sensors, and can determine a weighted mixing matrix 412 using the modeling inaccuracies. In some implementations, the modeling inaccuracies at the two or more magnetic field sensors can include an estimate of at least one of: an influence of non-linearities in the system, or magnetic field measurement noise levels. In some implementations, the system can determine locations of the two or more magnetic field sensors in order to increase the observability of the external magnetic field and the known disturbances relative to the modeling inaccuracies. For example, the system can choose the sensor locations to maximize the observability of the disturbance to the non-linearities, noise levels, etc. The system can generate a fused magnetic field output 414 representing the external magnetic field of the device including using the weighted mixing matrix 412 to scale the measurements from the magnetic field sensors. For example, the Magnetometer Fusion block 408 can include a signal fusion block 410 that can generate the fused magnetic field 414 from the measures 402 and 404 using the mixing matrix 412.

For example, with two magnetometers, the basic measurement Y can include the x, y, z measurements from each of the two magnetometers, e.g., Y=[x₁, y₁, z₁, x₂, y₂, z₂]^{T}. The measurement Y can have unknown levels of disturbances on each of the magnetometer measurements. The desired fused magnetometer output [x_{fused}, y_{fused}, z_{fused}]^{T}, is the body field (e.g., the external Earth field in the body coordinate system), with the disturbance components separated out. The system can model the relationship between the body field and the magnetometer measurements as a linear relationship, e.g., as following:

$$Y = HX + B . \qquad ( 9 )$$

Here, the vector X=[x_{body}, y_{body}, z_{body}, d1, d2, d3]^{T}, including the body field and the disturbances d1, d2, and d3. His an “observation matrix” describing how the body field and the disturbances impact the measurement Y and B=[bₓ_{₁}, b_{y}_{₁}, b_{z}_{₁}, bₓ_{₂}, b_{y}_{₂}, b_{z}_{₂}]^{T} is the magnetometer bias. The H matrix has the following structure:

$$H = [ \begin{matrix}1 & 0 & 0 & {c}_{{x}_{1} , {d}_{1}} & \text{?} & {c}_{{x}_{1} , {d}_{3}} \\ 0 & 1 & 0 & {c}_{{y}_{1} , {d}_{1}} & {c}_{{y}_{1} , {d}_{2}} & {c}_{{y}_{1} , {d}_{3}} \\ 0 & 0 & 1 & {c}_{{z}_{1} , {d}_{1}} & {c}_{{z}_{1} , {d}_{2}} & \text{?} \\ 1 & 0 & 0 & {c}_{{x}_{2} , {d}_{1}} & {c}_{{x}_{2} , {d}_{2}} & {c}_{{x}_{2} , {d}_{3}} \\ 0 & 1 & 0 & {c}_{{y}_{2} , {d}_{1}} & {c}_{{y}_{2} , {d}_{2}} & \text{?} \\ 0 & 0 & 1 & {c}_{{z}_{2} , {d}_{1}} & \text{?} & \text{?}\end{matrix} ] = [ \begin{matrix}{I}_{3} & {c}_{1 , {d}_{1}} & {c}_{1 , {d}_{2}} & {c}_{1 , {d}_{3}} \\ {I}_{3} & {c}_{2 , {d}_{1}} & {c}_{2 , {d}_{2}} & \text{?}\end{matrix} ]$$

$$\text{?} \text{indicates text missing or illegible when filed}$$

which encapsulates the measurement model, where the identity matrices reflect that the body field is measured directly for each axis, with contributions that are proportional to the level of disturbance. The effect of the disturbance on the measured signal is proportional to the coefficients c, where cₓ_{ᵢ}_{,d}_{ⱼ} reflect the scaling for disturbance j on the x-axis of sensor i, and similarly for the y and z axes for the sensors. Because H is invertible, the body field and disturbances may be estimated from the measurement field, e.g., as the following:

$$\hat{X} = {H}^{- 1} ( Y - B ) . \qquad ( 10 )$$

The system can determine the fused magnetometer output from the first three values of \hat{X}, e.g., as the following:

$${\hat{X}}_{fused} = {[ {x}_{fused} , {y}_{fused} , {z}_{fused} ]}^{T} = MY . \qquad ( 11 )$$

Here, M is a “mixing matrix” that defines the ratio used to mix the two magnetometer measurements. M can be derived from the observation matrix H, e.g., M=[H⁻¹]_{0:3,0:6}. Note that the fused magnetometer output can include a set of biases that can be estimated. For example, the set of biases can be a fixed linear combination of the biases for the two magnetometers, and the system can estimate the biases with bias estimation methods, e.g., the KASA method (e.g., Späth, Helmut. “Least-square fitting with spheres.” Journal of optimization theory and applications 96.1 (1998): 191-199), the MagGyro method (e.g., Troni, Giancarlo, and Louis L. Whitcomb. “Adaptive Estimation of Measurement Bias in Three-Dimensional Field Sensors with Angular Rate Sensors: Theory and Comparative Experimental Evaluation.” Robotics: Science and Systems. 2013), etc. The system can use the fused magnetometer output \hat{X}_{fused} as the baseline magnetometer signal and can provide the fused magnetometer output to the rest of the system.

In some implementations, the two magnetometers can include a primary magnetometer and a secondary magnetometer. The noise level at the secondary magnetometer location can be much larger than the noise level at the primary magnetometer location. The system can determine the fused magnetometer output by taking into consideration the different noise levels at the two magnetometer locations. For example, the system can model the relationship between the body field and the magnetometer measurements as a linear relationship, e.g., as following:

$$Y = HX + B + v . \qquad ( 12 )$$

Here, Y is the basic measurement that includes the measurements from each of the two magnetometers, e.g., Y=[x₁, y₁, z₁, x₂, y₂, z₂]^{T}. The vector X can include the body field and the disturbances. In some cases, the primary magnetometer can only be sensitive to a particular disturbance, and the particular disturbance can primarily be observed in one axis, e.g., the y axis. For example, the vector X can be [x_{body}, y_{body}, z_{body}, d]^{T}. H is the observation matrix describing how the disturbances impact the measurement. B is the magnetometer bias and υ is the noise on the measurements. Similar to the equation (11) in the example above, the system can determine the fused magnetometer output, e.g., as the following: \hat{X}_{fused}=[x_{fused}, y_{fused}, z_{fused}]^{T}=MY. Different from the example above, the system can generate the mixing matrix M that reduces the effect of the noise v on the fused magnetometer output.

In some implementations, the system can reduce the effect of the noise on the fused magnetometer output by using the estimated noise levels to change how the mixing matrix is calculated. The system can estimate the noise levels at the two magnetometers and can use the estimated noise levels to adjust the weighting that is used to calculate the mixing matrix. For example, the system can model the basic measurement as the following:

$$Y = H \tilde{X} + v . \qquad ( 13 )$$

Here, \tilde{X} includes the local body measurement and a projected bias, e.g., \tilde{X}=X+pinv(H)B. Assuming the probability distribution of the noise v is a zero-mean Gaussian distribution with a covariance Σ, e.g., v˜N(0, Σ), the system can split the covariance Σ into a primary magnetometer covariance matrix, a secondary magnetometer covariance matrix, and their cross covariance. The estimate of the \tilde{X} can be the \tilde{X} that minimizes a weighted least squares sum. For example, the estimated of the \tilde{X} can be the following:

$$[ {( Y - H \tilde{X} )}^{T} {\sum }^{- 1} ( Y - H \tilde{X} ) ] . \qquad ( 14 )$$

Thus, the estimate of the \tilde{X} can be derived as \tilde{\hat{X}}=(H^{T}Σ⁻¹H)⁻¹H^{T}Σ⁻¹Y. The system can determine the mixing matrix from the estimate of the \tilde{X}, as following:

$${M}_{weighted} = {[ {( {H}^{T} {\sum }^{- 1} H )}^{- 1} {H}^{T} {\sum }^{- 1} ]}_{0 : 3 , 0 : 6} . \qquad ( 15 )$$

The system can determine an estimate of the fused magnetometer output using the mixing matrix, e.g., as following:

$${\hat{\tilde{X}}}_{fused} = {[ {x}_{fused} , {y}_{fused} , {z}_{fused} ]}^{T} = {M}_{weighted} Y . \qquad ( 16 )$$

Note that the fused magnetometer output can include a set of biases that can be estimated. For example, the set of biases can be a fixed bias or can be from the modulo occasional re-magnetization events in the device. The system can estimate the biases with bias estimation methods, e.g., KASA or MagGyro.

In some implementations, the system can reduce the effect of the noise on the fused magnetometer output by ignoring the secondary magnetometer measurements in certain dimensions, e.g., x and z dimensions. In some implementations, the primary magnetometer can be only sensitive to motion of a disturbance, and the disturbance can primarily show up in the y axis. The system can ignore the x and z components in the measurement from the secondary magnetometer. Thus, the basic measurement Y can be Y=[x₁, y₁, z₁, y₂]^{T}. The dimensionality of the observation matrix H and the bias B can be correspondingly reduced. Thus, the mixing matrix can be expressed as M=[H⁻¹]_{0:3,0:4}. Because the sensitivity in the x and z dimensions is fairly small for the primary magnetometer, the mixing matrix can be simplified by rounding the x and z dimension sensitivities to zero, e.g.,

$$M ∼ [ \begin{matrix}1 & 0 & 0 & 0 \\ 0 & {a}_{2 , 2} & 0 & {a}_{2 , 4} \\ 0 & 0 & 1 & 0\end{matrix} ] . \qquad ( 17 )$$

In some implementations, the fusion result can be obtained from a combination of magnetic field sensors, where Y=[m₁, m₂, . . . , mₙ], where each mᵢ corresponds to a single axis measurement (e.g., obtained from a single-axis magnetometer). For example, for the above case, m₁, m₂, and m₃ can correspond to the x, y, and z axes for the first magnetometer. For this case, the H matrix can be:

$$H = [ \begin{matrix}{a}_{{m}_{1} , {x}_{body}} & {a}_{{m}_{1} , {y}_{body}} & {a}_{{m}_{1} , {z}_{body}} & {c}_{{m}_{1} , {d}_{1}} & \text{?} & {c}_{{m}_{1} , {d}_{3}} \\ {a}_{{m}_{2} , {x}_{body}} & {a}_{{m}_{2} , {y}_{body}} & {a}_{{m}_{2} , {z}_{body}} & {c}_{{m}_{2} , {d}_{1}} & {c}_{{m}_{2} , {d}_{2}} & {c}_{{m}_{3} , {d}_{3}} \\ ⋮ & ⋮ & ⋮ & ⋮ & ⋮ & ⋮ \\ \text{?} & \text{?} & \text{?} & \text{?} & \text{?} & \text{?}\end{matrix} ] ,$$

$$\text{?} \text{indicates text missing or illegible when filed}$$

where aₘ_{ᵢ}_{,x}_{_{body}}, aₘ_{ᵢ}_{,y}_{_{body}}, aₘ_{ᵢ}_{,z}_{_{body}} reflects how the sensor measures the body-frame magnetic field. The fused output can then be obtained from either the weighted or unweighted formulations described previously. In some implementations, given sufficient measurements, the system can generate fused measurements using different combinations of sensor measurements. The system can apply the sensor quality evaluation techniques described above, or can apply a least-squares residual technique to assess the disturbances that are coming from hard-iron changes or local field variation.

In some implementations, the system 400 can include a magnetic field sensor quality evaluation block 418. The magnetic field sensor quality evaluation block 418 can receive the fused magnetic field 414 (and optionally, the additional fused magnetic field outputs 416) as input. The magnetic field sensor quality evaluation block 418 can analyze the one or more fused magnetic fields and can evaluate the magnetic field sensor quality of the one or more fused magnetic fields. For example, the magnetic field sensor quality evaluation block 418 can include one or more of the blocks 212, 214, and 216 of the example system 200 in FIG. 2 that can perform calibration quality control using multiple magnetic field sensors.

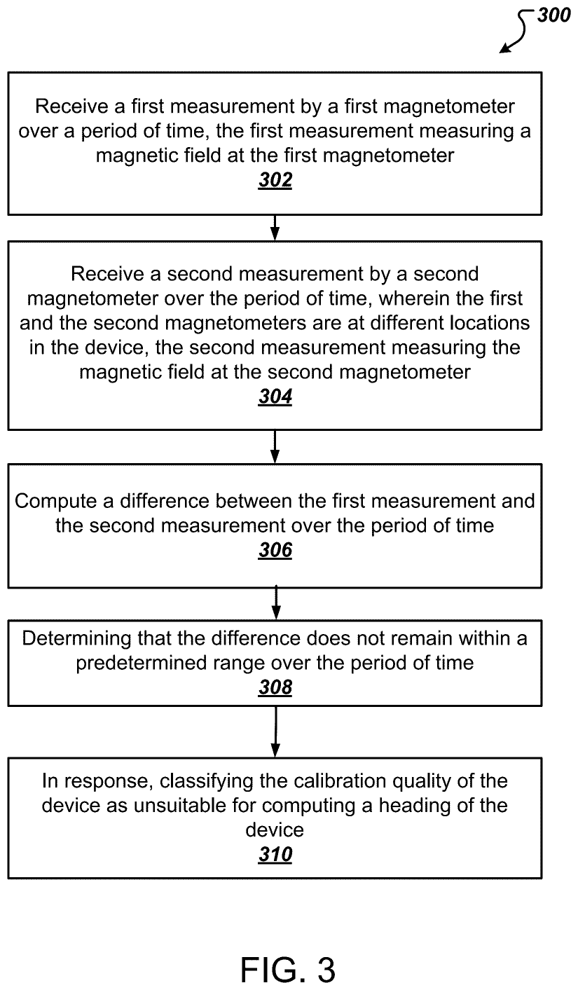

FIG. 3 is a flowchart of an example for calibration quality control using multiple magnetometers. For convenience, the process 300 will be described as being performed by a system for calibration quality control using multiple magnetometers, for example, the system 200 in FIG. 2. The system can include the components of an electronic device 100 described in reference to FIG. 1, including one or more sensors, e.g., the multiple magnetometers, one or more SoCs, one or more memory devices, and one or more storage devices, or some combination of these.

The system receives measurements by two or more magnetic field sensors of the device over a period of time. For example, the device can include one, two, three, or more magnetic field sensors. Each measurement can measure a magnetic field at each magnetic field sensor. Each measurement at each time point over the period of time can include a vector in one or more spatial axes of a three-dimensional (3D) space. For example, the vector can be in one, two, or three sensing spatial axes in the 3D space.

In some implementations, the two or more magnetic field sensors can include two or more magnetometers. In some implementations, the system receives a first measurement by a first magnetometer over a period of time (302). The first measurement can measure a magnetic field at the first magnetometer. For example, the first measurement at each time point over the period of time can be a first three-dimensional (3D) vector in x, y, and z, measuring a magnetic field at the first magnetometer.

In some implementations, the system can receive a second measurement by a second magnetometer over the period of time (304). The first magnetometer and the second magnetometer are at different locations in the device. The second measurement can measure the magnetic field at the second magnetometer. For example, the second measurement at each time point over the period of time can be a second 3D vector in x, y, and z, measuring the magnetic field at the second magnetometer.

The system computes a difference between the measurements by the two or more magnetic field sensors over the period of time, and the difference at each time point over the period of time can be a result of computing a difference based on one or more pairs of the vectors at the time point. In some implementations, the system can compute a difference between the first measurement and the second measurement over the period of time (306). The difference at each time point over the period of time can be a result of subtracting the second 3D vector from the first 3D vector at the time point. In some implementations, the difference at each time point over the period of time can be a result of computing the difference of the norms of the one or more pairs of the vectors at the time point.

The system determines that the difference does not remain within a predetermined range over the period of time (308). In response to determining that the difference does not remain within a predetermined range over the period of time, the system classifies the calibration quality of the device as unsuitable for higher system-level magnetic field sensor usage, e.g. computing a heading of the device (310). For example, the system can determine to bypass computing a heading of the device using the first measurement, the second measurement, or both.

In some implementations, the system can determine that the difference remains inside the predetermined range over the period of time. In response, the system can classify the calibration quality of the device as suitable for computing a heading. For example, based on the first and second measurements, the system can determine that the magnetic field is independent of the location and orientation of the device because the difference between the measurements can be close to zero. The system can determine that the difference remains to be close to zero as the device moves in a 3D space over a period of time. The system can determine that the magnetic field is a homogeneous magnetic field, e.g., the Earth field. The system can determine that the device is well calibrated and the system can use the measurements to compute a heading of the device.

In some implementations, the first measurement and the second measurement can be measured over the period of time while the device is moving. The system can compare the difference to a non-zero constant over the period of time. The system can determine that the difference stays near the non-zero constant over the period of time. In response, the system can determine that the calibration quality can be affected or impacted by a non-homogeneous static field inside the device. For example, the system can determine that the calibration quality has decreased due to a change in the non-homogenous static field inside the device. Under the non-homogeneous static field, the measurements from the two magnetometers can be different on average, and the difference between the measurements can remain inside a predetermined range over a period of time as the device moves in a 3D space.

For example, a magnetized component in the device can cause a non-homogeneous but static field, e.g., a hard iron field 106. When the device moves over the period of time, because the relative positions of the magnetized component to each of the magnetometers remain the same, both the first measurement and the second measurement can remain unchanged over the period of time. Thus, the difference between the first measurement and the second measurement over the period of time can stay near the non-zero constant, e.g., remain unchanged.

In some implementations, after classifying the calibration quality of the device as unsuitable for computing a heading of the device, the system can calibrate the device, e.g., by triggering a calibration routine of the device. After calibration, the system can use the first measurement, the second measurement, or both, to compute the heading of the device.

In some implementations, the system can trigger a calibration routine by comparing the non-zero constant to a threshold. For example, if the non-zero constant is larger than a threshold, the system can trigger the calibration routine to calibrate the device. In some implementations, the system can calibrate the device, e.g., by triggering the calibration routine of the device. For example, referring to equation (8), the non-zero constant, can be formulated as

$$Δ {H}_{HI} ( \frac{1}{{r}_{1}} - \frac{1}{{r}_{2}} ) .$$

If the position of the first magnetometer and the second magnetometer is known, the value

$$( \frac{1}{{r}_{1}} - \frac{1}{{r}_{2}} )$$

can be computed using the relative distance r from each of the magnetometer to the center of the hard iron field. Thus, the hard iron change ΔH_{HI} can be computed. An offset can be computed as

$$\frac{Δ {H}_{HI}}{r} ,$$

and the offset can be used to calibrate the device.

In some implementations, the system can calibrate the device, e.g., by triggering a calibration routine of the device. After the calibration is completed, the system can receive updated measurements by the two or more magnetic field sensors of the device over a second period of time. The system can compute a difference between the updated measurements by the two or more magnetic field sensors. The system can determine whether the difference remains inside the predetermined range over the second period of time. If the system determines that the difference remains inside the predetermined range over the second period of time, the system can classify the calibration quality of the device as suitable for computing the heading of the device, and the system can use at least one of the updated measurements to compute the heading of the device. If the system determines that the difference does not remain inside the predetermined range over the second period of time, the system can perform additional calibration of the calibration quality of the device, e.g., to improve the accuracy of the magnetometer measurements.

In some implementations, the first measurement and the second measurement can be measured over the period of time while the device is moving. The system can determine that the difference does not stay near the non-zero constant over the period of time. In response, the system can determine that the calibration quality can be affected by a non-homogeneous and non-static field. For example, an external component outside the device can cause a non-homogeneous and non-static field. As another example, the device can include a moving component that has a large magnet attached to it, and the moving component inside the device can cause a non-homogeneous and non-static field. Under the non-homogeneous non-static field, the measurements from the two magnetometers can be different on average, and the difference between the measurements may not remain inside a predetermined range over a period of time over time as the device is moving in a 3D space.

In some implementations, the system can perform the process 300 for the calibration quality control using multiple magnetometers at a predetermined interval, e.g., every 10 seconds or every 5 minutes. Instead of performing an “always on” field monitoring that has a high power cost, the system can measure the difference of the measurements from the multiple magnetometers at a predetermined interval and can use the difference to determine the calibration quality of the device. The system can automatically determine to calibrate the magnetometers if the difference is stable but away from zero. Thus, the system can lower the power consumption significantly even though multiple magnetometers are running in the device.

In some implementations, the system can self-calibrate against internal disturbances. In some implementations, the device itself can provide known magnetic field changes or disturbances to the system of the device, and the system can self-generate a mixing matrix for the computation of a fusion of the measurements by the sensitivities to the disturbances measured by the two or more magnetic field sensors. For example, during a period of time when the device is not moving, the device can force the internal camera Voice Coil Motors (VCM) magnet into different physical positions within the device. The system can measure the response in each of the magnetometers, and can re-estimate the mixing matrix for the fusion computation. In some implementations, the disturbance response can be estimated without actively controlling the disturbance parameters, e.g. by using Principal Component Analysis on the field deviations when the device is stationary.

In some implementations, the noise levels used to compute the mixing matrix are reflective of measurement noise at the sensor. In some implementations, the noise level is reflective of non-linearities or other modeling inaccuracies of the linear measurement model.

In some implementations, after the calibration of the device is completed, the system can determine whether the calibration is a good calibration. The system can obtain updated measurements from the two magnetometers. The system can compute calibrated measurements from the updated measures using the offsets determined during the calibration. The system can determine whether a difference between the calibrated measurements remains inside a predetermined range, e.g., close to zero, over the period of time while the device is moving. If the system determines that the difference is close to zero, the system can determine that the calibration quality of the device is good. If the system determines that the difference is not close to zero, the system can determine that the calibration quality of the device is not good, and the system can determine to perform additional calibration of the device.

Embodiments of the subject matter and the actions and operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. Alternatively or in addition, the program instructions can be encoded on an artificially-generated propagated signal, e.g., a machine-generated electrical, optical, or electromagnetic signal that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

A computer program, which may also be referred to or described as a program, software, a software application, an app, a module, a software module, an engine, a script, or code, can be written in any form of programming language, including compiled or interpreted languages, or declarative or procedural languages; and it can be deployed in any form, including as a stand-alone program or as a module, component, engine, subroutine, or other unit suitable for executing in a computing environment, which environment may include one or more computers interconnected by a data communication network in one or more locations.

A computer program may, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

To provide for interaction with a user, embodiments of the subject matter described in this specification can be implemented on, or configured to communicate with, a computer having a display device, e.g., a LCD (liquid crystal display) monitor, for displaying information to the user, and an input device by which the user can provide input to the computer, e.g., a keyboard and a pointing device, e.g., a mouse, a trackball or touchpad. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser, or by interacting with an app running on a user device, e.g., a smartphone or electronic tablet. Also, a computer can interact with a user by sending text messages or other forms of message to a personal device, e.g., a smartphone that is running a messaging application, and receiving responsive messages from the user in return.

Embodiments of the subject matter described in this specification can be implemented in a computing system that includes a back-end component, e.g., as a data server, or that includes a middleware component, e.g., an application server, or that includes a front-end component, e.g., a client device having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

In addition to the embodiments described above, the following embodiments are also innovative:

Embodiment 1 is a method for determining a calibration quality of a device, comprising:
receiving measurements by two or more magnetic field sensors of the device over a period of time, wherein each measurement measures a magnetic field at each magnetic field sensor, wherein each measurement at each time point over the period of time comprises a vector in one or more spatial axes of a three-dimensional space;
computing a difference between the measurements by the two or more magnetic field sensors over the period of time, wherein the difference at each time point over the period of time is a result of computing a difference based on one or more pairs of the vectors at the time point;
determining that the difference does not remain within a predetermined range over the period of time; and
in response, classifying the calibration quality of the device as unsuitable for computing a heading of the device.

Embodiment 2 is the method of claim 1, wherein the measurements are measured over the period of time while the device is moving, the method comprising:
comparing the difference to a non-zero constant over the period of time;
determining that the difference stays near the non-zero constant over the period of time; and
in response, determining that the calibration quality is affected by a non-homogeneous static field inside the device.

Embodiment 3 is the method of claim 2, further comprising:
triggering a calibration routine of the device.

Embodiment 4 is the method of claim 2, further comprising:
determining that the difference does not stay near the non-zero constant over the period of time; and
in response, determining that the calibration quality is affected by a non-homogeneous field outside the device.

Embodiment 5 is the method of claim 1, comprising:
determining that the difference remains inside the predetermined range over the period of time; and
in response, classifying the calibration quality of the device as suitable for computing the heading of the device.

Embodiment 6 is the method of claim 1, comprising:
triggering a calibration routine of the device;
receiving updated measurements by the two or more magnetic field sensors of the device over a second period of time;
computing a difference between the updated measurements by the two or more magnetic field sensors;
determining whether the difference remains inside the predetermined range over the second period of time; and
in response to determining that the difference remains inside the predetermined range over the second period of time, classifying the calibration quality of the device as suitable for computing the heading of the device.

Embodiment 7 is the method of claim 6, comprising:
using at least one of the updated measurements to compute the heading of the device.

Embodiment 8 is the method of claim 6, comprising:
in response to determining that the difference does not remain inside the predetermined range over the second period of time, performing additional calibration of the calibration quality of the device.

Embodiment 9 is the method of claim 1, wherein the two or more magnetic field sensors comprise two or more magnetometers.

Embodiment 10 is a method, comprising:
receiving measurements by two or more magnetic field sensors of a device over a period of time, wherein each measurement measures a magnetic field at each magnetic field sensor;
estimating modeling inaccuracies at the two or more magnetic field sensors;
determining a weighted mixing matrix using the modeling inaccuracies; and
generating a fused magnetic field output representing an external magnetic field of the device including using the weighted mixing matrix to scale the measurements from the magnetic field sensors.

Embodiment 11 is the method of claim 10, wherein the two or more magnetic field sensors comprise two or more magnetometers.

Embodiment 12 is the method of claim 10, wherein the modeling inaccuracies at the two or more magnetic field sensors comprise an estimate of at least one of: an influence of non-linearities, or magnetic field measurement noise levels.

Embodiment 13 is a system comprising one or more computers and one or more storage devices storing instructions that are operable, when executed by the one or more computers, to cause the one or more computers to perform operations comprising:
receiving measurements by two or more magnetic field sensors of a device over a period of time, wherein each measurement measures a magnetic field at each magnetic field sensor, wherein each measurement at each time point over the period of time comprises a vector in one or more spatial axes of a three-dimensional space;
computing a difference between the measurements by the two or more magnetic field sensors over the period of time, wherein the difference at each time point over the period of time is a result of computing a difference based on one or more pairs of the vectors at the time point;
determining that the difference does not remain within a predetermined range over the period of time; and
in response, classifying calibration quality of the device as unsuitable for computing a heading of the device.

Embodiment 14 is one or more non-transitory storage media encoded with instructions that when executed by a computing device cause the computing device to perform operations comprising:
receiving measurements by two or more magnetic field sensors of a device over a period of time, wherein each measurement measures a magnetic field at each magnetic field sensor, wherein each measurement at each time point over the period of time comprises a vector in one or more spatial axes of a three-dimensional space;
computing a difference between the measurements by the two or more magnetic field sensors over the period of time, wherein the difference at each time point over the period of time is a result of computing a difference based on one or more pairs of the vectors at the time point;
determining that the difference does not remain within a predetermined range over the period of time; and
in response, classifying calibration quality of the device as unsuitable for computing a heading of the device.

While this specification contains many specific implementation details, these should not be construed as limitations on the scope of any invention or on the scope of what is being or may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claim may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A method for determining a calibration quality of a device, comprising:
receiving measurements by two or more magnetic field sensors of the device over a period of time, wherein each measurement measures a magnetic field at each magnetic field sensor, wherein each measurement at each time point over the period of time comprises a vector in one or more spatial axes of a three-dimensional space;
computing a difference between the measurements by the two or more magnetic field sensors over the period of time, wherein the difference at each time point over the period of time is a result of computing a difference based on one or more pairs of the vectors at the time point;
determining that the difference does not remain within a predetermined range over the period of time; and
in response, classifying the calibration quality of the device as unsuitable for computing a heading of the device.

2. The method of claim 1, wherein the measurements are measured over the period of time while the device is moving, the method comprising:
comparing the difference to a non-zero constant over the period of time;
determining that the difference stays near the non-zero constant over the period of time; and
in response, determining that the calibration quality is affected by a non-homogeneous static field inside the device.

3. The method of claim 2, further comprising:
triggering a calibration routine of the device.

4. The method of claim 2, further comprising:
determining that the difference does not stay near the non-zero constant over the period of time; and
in response, determining that the calibration quality is affected by a non-homogeneous field outside the device.

5. The method of claim 1, comprising:
determining that the difference remains inside the predetermined range over the period of time; and
in response, classifying the calibration quality of the device as suitable for computing the heading of the device.

6. The method of claim 1, comprising:
triggering a calibration routine of the device;
receiving updated measurements by the two or more magnetic field sensors of the device over a second period of time;
computing a difference between the updated measurements by the two or more magnetic field sensors;
determining whether the difference remains inside the predetermined range over the second period of time; and
in response to determining that the difference remains inside the predetermined range over the second period of time, classifying the calibration quality of the device as suitable for computing the heading of the device.

7. The method of claim 6, comprising:
using at least one of the updated measurements to compute the heading of the device.

8. The method of claim 6, comprising:
in response to determining that the difference does not remain inside the predetermined range over the second period of time, performing additional calibration of the calibration quality of the device.

9. The method of claim 1, wherein the two or more magnetic field sensors comprise two or more magnetometers.

10. A method, comprising:
receiving measurements by two or more magnetic field sensors of a device over a period of time, wherein each measurement measures a magnetic field at each magnetic field sensor;
estimating modeling inaccuracies at the two or more magnetic field sensors;
determining a weighted mixing matrix using the modeling inaccuracies; and
generating a fused magnetic field output representing an external magnetic field of the device including using the weighted mixing matrix to scale the measurements from the magnetic field sensors.

11. The method of claim 10, wherein the two or more magnetic field sensors comprise two or more magnetometers.

12. The method of claim 10, wherein the modeling inaccuracies at the two or more magnetic field sensors comprise an estimate of at least one of: an influence of non-linearities, or magnetic field measurement noise levels.

13. A system comprising one or more computers and one or more storage devices storing instructions that are operable, when executed by the one or more computers, to cause the one or more computers to perform operations comprising:
receiving measurements by two or more magnetic field sensors of a device over a period of time, wherein each measurement measures a magnetic field at each magnetic field sensor, wherein each measurement at each time point over the period of time comprises a vector in one or more spatial axes of a three-dimensional space;
computing a difference between the measurements by the two or more magnetic field sensors over the period of time, wherein the difference at each time point over the period of time is a result of computing a difference based on one or more pairs of the vectors at the time point;
determining that the difference does not remain within a predetermined range over the period of time; and
in response, classifying calibration quality of the device as unsuitable for computing a heading of the device.

14. The system of claim 13, wherein the measurements are measured over the period of time while the device is moving, the operations comprises:
comparing the difference to a non-zero constant over the period of time;
determining that the difference stays near the non-zero constant over the period of time; and
in response, determining that the calibration quality is affected by a non-homogeneous static field inside the device.

15. The system of claim 14, the operations further comprise:
triggering a calibration routine of the device.

16. The system of claim 14, the operations further comprise:
determining that the difference does not stay near the non-zero constant over the period of time; and
in response, determining that the calibration quality is affected by a non-homogeneous field outside the device.

17. The system of claim 13, the operations comprise:
determining that the difference remains inside the predetermined range over the period of time; and
in response, classifying the calibration quality of the device as suitable for computing the heading of the device.

18. The system of claim 13, the operations comprise:
triggering a calibration routine of the device;
receiving updated measurements by the two or more magnetic field sensors of the device over a second period of time;
computing a difference between the updated measurements by the two or more magnetic field sensors;
determining whether the difference remains inside the predetermined range over the second period of time; and
in response to determining that the difference remains inside the predetermined range over the second period of time, classifying the calibration quality of the device as suitable for computing the heading of the device.

19. The system of claim 18, the operations comprise:
using at least one of the updated measurements to compute the heading of the device.

20. One or more non-transitory storage media encoded with instructions that when executed by a computing device cause the computing device to perform operations comprising:
receiving measurements by two or more magnetic field sensors of a device over a period of time, wherein each measurement measures a magnetic field at each magnetic field sensor, wherein each measurement at each time point over the period of time comprises a vector in one or more spatial axes of a three-dimensional space;
computing a difference between the measurements by the two or more magnetic field sensors over the period of time, wherein the difference at each time point over the period of time is a result of computing a difference based on one or more pairs of the vectors at the time point;
determining that the difference does not remain within a predetermined range over the period of time; and
in response, classifying calibration quality of the device as unsuitable for computing a heading of the device.
